(19) United States
(12) Patent Application Publication
(10) Pub. No.: US 2025/0277117 A1
(43) Pub. Date: Sep. 4, 2025

(54) AN AMPHIPHOBIC COATING AND METHOD OF PREPARING AN AMPHIPHOBIC COATING

(71) Applicant: NANYANG TECHNOLOGICAL UNIVERSITY, Singapore (SG)

(72) Inventors: Zhong CHEN, Singapore (SG); Rajdeep Singh RAWAT, Singapore (SG); Ye SUN, Singapore (SG)

(21) Appl. No.: 18/857,755

(22) PCT Filed: Apr. 18, 2023
(86) PCT No.: PCT/SG2023/050258

§ 371 Date: Oct. 17, 2024

(30) Foreign Application Priority Data
Apr. 19, 2022 (SG) 10202204021P

(51) Int. Cl. C09D 5/16; C08J 7/056; C08J 7/06; C09D 1/00; C09D 7/40; C23C 14/02; C23C 14/10; C23C 14/28

(52) U.S. Cl. CPC C09D 5/1693; C08J 7/056; C08J 7/065; C09D 1/00; C09D 5/1662; C09D 7/67; C23C 14/02; C23C 14/10; C23C 14/28

(57) ABSTRACT

An amphiphobic coating is provided. The amphiphobic coating comprises a polymeric substrate having an oxygen plasma-treated surface; a silicon dioxide layer comprising silicon dioxide nanoparticles disposed directly on the oxygen plasma-treated surface; and a fluoroalkylsilane layer disposed directly on the silicon dioxide layer. Method of preparing an amphiphobic coating and use thereof are also provided.

### CROSS-REFERENCE TO RELATED APPLICATION

This application claims the benefit of priority of Singapore patent application no. 10202204021P, filed 19 Apr. 2022, the contents of which being hereby incorporated by reference in its entirety for all purposes.

### TECHNICAL FIELD

Various embodiments relate to an amphiphobic coating, a method of preparing an amphiphobic coating, uses of the coating and an article of manufacture comprising the coating.

### BACKGROUND

Good light transmittance and surface cleanliness are amongst the most important requirements for optical products such as lenses, screens, and shields. These requirements are challenging to meet, however, as it is easy to impart contaminants such as fingerprint, skin oil residue, and dust particles to the optical products during handling or service, which affect transparency and sometimes aesthetic value of the product.

To mitigate the impact of such issues, extensive research on surface modification has been carried out. For example, in order to confer surfaces with anti-fingerprint and self-cleaning properties, surfaces with highly anti-wetting properties against both water and oil, termed as superamphiphobic surfaces, have generated enormous interest in recent years.

Although nature has inspired us with examples of superhydrophobic surfaces such as lotus leaves, and insects' legs and wings, and strategies have been developed to construct superhydrophobic surfaces, fabricating of superamphiphobic surfaces remains challenging as surface tension of oil is much lower than water. This makes it difficult to realize surfaces which are both water and oil repellent.

In the case for optical products, challenges also lie with potential conflict between requirements for amphiphobicity and transparency. A high degree of surface roughness is often desirable for superamphiphobicity. However, light transmittance may be reduced with increase in surface roughness due to increased light scattering. Therefore, it is challenging to achieve both superamphiphobicity and high light transmittance.

Polymeric optical lenses have attracted significant attention, especially for applications in medical and consumer products, due to advantages of light weight, greater resistance to mechanical impact, and adaptability for making into sophisticated shapes. Substantial growth in demand for polymeric materials to replace oxide glass has been observed. There is a need to functionalize polymer material surfaces with self-cleaning and anti-fingerprint properties while retaining high light transmittance. Work on fabricating transparent amphiphobic coating on polymeric substrates is rare, however, due to challenges relating to low melting point of polymer materials and their inert chemical properties. Most of the developed fabrication methods require a high temperature calcination process, which is not suitable for heat sensitive polymeric materials. In addition, mechanical stability, especially adhesion between coating and substrate, remains a major challenge for coatings on polymeric substrates.

In light of the above, there remains a need for an improved coating and method of preparing a coating that overcomes or at least alleviates one or more of the above-mentioned problems.

### SUMMARY

Various embodiments refer in a first aspect to an amphiphobic coating. The amphiphobic coating comprises a polymeric substrate having an oxygen plasma-treated surface; a silicon dioxide layer comprising silicon dioxide nanoparticles disposed directly on the oxygen plasma-treated surface; and a fluoroalkylsilane layer disposed directly on the silicon dioxide layer.

Various embodiments refer in a second aspect to a method of preparing an amphiphobic coating. The method comprises providing a polymeric substrate having an oxygen plasma-treated surface; depositing silicon dioxide directly on the oxygen plasma-treated surface by pulsed laser deposition to form a silicon dioxide layer comprising silicon dioxide nanoparticles; and depositing a fluoroalkylsilane directly on the silicon dioxide layer to form a fluoroalkylsilane layer on the silicon dioxide layer.

Various embodiments refer in a third aspect to an amphiphobic coating prepared by a method according to the second aspect.

Various embodiments refer in a fourth aspect to use of an amphiphobic coating according to the first aspect or an amphiphobic coating prepared by a method according to the second aspect in anti-reflection coatings, anti-fingerprint coatings, anti-fouling coatings, self-cleaning surfaces, primer layer for surfaces, optical components, sensors, lens, goggles, mirrors, windshields, face shields, displays, windows, or cookware covers.

Various embodiments refer in a fifth aspect to an article of manufacture comprising an amphiphobic coating according to the first aspect or an amphiphobic coating prepared by a method according to the second aspect, wherein the article is an optical component, sensor, lens, goggles, mirror, windshield, face shield, display, window, or cookware covers.

### BRIEF DESCRIPTION OF THE DRAWINGS

In the drawings, like reference characters generally refer to the same parts throughout the different views. The drawings are not necessarily drawn to scale, emphasis instead generally being placed upon illustrating the principles of various embodiments. In the following description, various embodiments of the invention are described with reference to the following drawings.

FIG. 1 is a schematic diagram for preparing an amphiphobic coating 100 according to an embodiment. In the embodiment shown, a polymeric substrate 101 is provided. The polymeric substrate 101 may be subjected to processing conditions 112 of being cleaned with deionized (DI) water and ethanol, and be subjected to surface treatment with oxygen plasma. In so doing, this may increase surface roughness and alter surface chemistry of the oxygen plasma treated surface 103 with more oxygen bonding. Silicon dioxide (SiO₂) may be deposited directly on the oxygen plasma-treated surface 103 by pulsed laser deposition 114 to form superhydrophilic film 105 of silica nanoparticles with abundant hydroxy groups on a surface of the superhydrophilic film 105. The superhydrophilic film 105 of silica nanoparticles may undergo a fluoroalkylsilane treatment 116. The fluoroalkylsilane may undergo self-assembly and react with the hydroxy groups on the surface of the superhydrophilic film 105 of silica nanoparticles to form a fluoroalkylsilane layer 107. An amphiphobic coating 100 which is superhydrophobic and oleophobic may be formed.

In an exemplified embodiment, a polycarbonate substrate is provided. The polycarbonate substrate is cleaned with deionized (DI) water and ethanol, and subjected to surface treatment with oxygen plasma for about 15 minutes. In so doing, this may increase surface roughness and alter surface chemistry of the oxygen plasma treated surface with more oxygen bonding. Silicon dioxide (SiO₂) is deposited directly on the oxygen plasma-treated surface by pulsed laser deposition for about 60 minutes to form a superhydrophilic film of silica nanoparticles with abundant hydroxy groups on a surface of the superhydrophilic film. The superhydrophilic film of silica nanoparticles is treated with trichloro (1H,1H,2H,2H-perfluorooctyl) silane (PFTS) for about 10 minutes with heat for about 2 hours. The trichloro (1H,1H,2H,2H-perfluorooctyl) silane undergoes self-assembly and reacts with the hydroxy groups on the surface of the superhydrophilic film of silica nanoparticles to form an amphiphobic coating which is superhydrophobic and oleophobic.

FIG. 2A depicts surface topography observed under scanning electron microscope (SEM) at 10 min deposition duration. Scale bar denotes 100 nm.

FIG. 2B depicts surface topography observed under atomic force microscope (AFM) at 10 min deposition duration.

FIG. 2C depicts surface topography observed under atomic force microscope (AFM) at 10 min deposition duration.

FIG. 2D depicts surface topography observed under scanning electron microscope (SEM) at 30 min deposition duration. Scale bar denotes 100 nm.

FIG. 2E depicts surface topography observed under atomic force microscope (AFM) at 30 min deposition duration.

FIG. 2F depicts surface topography observed under atomic force microscope (AFM) at 30 min deposition duration.

FIG. 2G depicts surface topography observed under scanning electron microscope (SEM) at 60 min deposition duration. Scale bar denotes 100 nm.

FIG. 2H depicts surface topography observed under atomic force microscope (AFM) at 60 min deposition duration.

FIG. 2I depicts surface topography observed under atomic force microscope (AFM) at 60 min deposition duration.

FIG. 2J depicts surface topography observed under scanning electron microscope (SEM) at 90 min deposition duration. Scale bar denotes 100 nm.

FIG. 2K depicts surface topography observed under atomic force microscope (AFM) at 90 min deposition duration.

FIG. 2L depicts surface topography observed under atomic force microscope (AFM) at 90 min deposition duration.

FIG. 3A shows water contact angle comparison at different deposition duration before and after abrasion testing.

FIG. 3B shows oil contact angle comparison at different deposition duration before and after abrasion testing.

FIG. 4 shows profiles of water contact angle (WCA) of silica nanoparticle film (401), water contact angle (WCA) of silica nanoparticle film after PFTS coating (403), oil contact angle (OCA) of silica nanoparticle film (405), and oil contact angle (OCA) of silica nanoparticle film after PFTS coating (407).

FIG. 5A shows field emission SEM and AFM images of surface morphology of as-prepared silica nanoparticle film with PFTS coating.

FIG. 5B shows field emission SEM and AFM images of surface morphology of as-prepared silica nanoparticle film without PFTS coating.

FIG. 6A shows AFM topographical image and roughness measurement of pristine PC surface.

FIG. 6B shows AFM topographical image and roughness measurement of oxygen plasma treated PC surface.

FIG. 6C shows (from top to bottom) X-ray Photoelectron Spectroscopy (XPS) survey spectra of oxygen plasma treated PC and pristine PC.

FIG. 7A shows (from top to bottom) survey XPS spectra comparison between pristine PC, silica film, and PFTS coated silica nanoparticle film on polycarbonate substrate.

FIG. 7B shows high resolution fitted XPS spectra of C 1s of PFTS coated silica film.

FIG. 7C shows high resolution fitted XPS spectra of O 1s of PFTS coated silica film.

FIG. 7D shows high resolution fitted XPS spectra of Si 2p of PFTS coated silica film.

FIG. 7E shows high resolution fitted XPS spectra of F 1s of PFTS coated silica film.

FIG. 8A shows the as-prepared PFTS coated silica nanoparticle film, demonstrating transparency with repellence of water and oil.

FIG. 8B shows light transmittance measured with UV-vis spectrometer for pristine PC and PFTS coated silica film.

FIG. 8C shows digital image of presenting transparency anti-fingerprint property, whereby pristine PC with fingerprint is shown.

FIG. 8D shows digital image of presenting transparency anti-fingerprint property, whereby PFTS coated silica nanoparticle film without fingerprint is shown.

FIG. 8E shows self-cleaning process for pristine PC and silica nanoparticle film/PFTS coated PC.

FIG. 9 shows light transmittance at visible range for different film deposition duration of 10 min, 30 min, 60 min, and 90 min, as well as that of pristine polycarbonate. Based on the results obtained, light transmittance at visible range (T %ₐᵥₑ) of the coated samples are even higher than that obtained for pristine polycarbonate with no coating.

FIG. 10A shows field emission SEM image of crosshatched as-prepared coated PC surface.

FIG. 10B shows field emission SEM image of PC surface after abrasion test. Insert is the field emission SEM image of as-prepared coating as comparison.

FIG. 10C shows AFM topography image and surface roughness measurement for coated PC surface after abrasion testing.

FIG. 10D shows water contact angle (WCA) and oil contact angle (OCA) after abrasion test. Diiodomethane was used as an oil sample for the oil contact angle measurement.

FIG. 10E shows transmittance measurement comparison between pristine PC, as-prepared coated PC and after abrasion test.

FIG. 10F shows microscopic image of fingerprint on PC surface after abrasion test. Insert is microscopic image of fingerprint on surface without coating.

### DESCRIPTION

The following detailed description refers to the accompanying drawings that show, by way of illustration, specific details and embodiments in which the invention may be practised. These embodiments are described in sufficient detail to enable those skilled in the art to practise the invention. Other embodiments may be utilized and structural, logical, and electrical changes may be made without departing from the scope of the invention. The various embodiments are not necessarily mutually exclusive, as some embodiments can be combined with one or more other embodiments to form new embodiments.

Various embodiments refer in a first aspect to an amphiphobic coating. As used herein, the term “amphiphobic” refers to compounds or coatings which repel both water-based and oil-based substances. The term “water-based substance” may refer to a liquid with water as major phase. For example, water content in the water-based substance may be at least 50% by weight of the substance, such as at least 60%, at least 65%, at least 70%, at least 75%, at least 80%, at least 85%, at least 90%, or at least 95%. Likewise, the term “oil-based” may refer to a liquid with oil as major phase. For example, oil content in the oil-based substance may be at least 50% by weight of the substance, such as at least 60%, at least 65%, at least 70%, at least 75%, at least 80%, at least 85%, at least 90%, or at least 95%. The oil may be in the form of an optionally substituted hydrocarbon, and examples of the oil-based substance may include sebum and oil from skin.

Accordingly, the amphiphobic coating disclosed herein may be hydrophobic as well as oleophobic, in that water contact angle and oil contact angle of the amphiphobic coating may respectively be equal to or more than 90°. In various embodiments, the amphiphobic coating disclosed herein is superhydrophobic, meaning that contact angle between a droplet of water and a surface formed by the amphiphobic coating is more than 150°. In various embodiments, the amphiphobic coating disclosed herein is highly oleophobic, meaning that contact angle between a droplet of oil (as exemplified by diiodomethane) and a surface formed by the amphiphobic coating is more than 130°.

Advantageously, coatings according to embodiments disclosed herein are capable of exhibiting self-cleaning properties, which refers to inherent ability of a surface to keep clean over time, in the absence of, or with reduced need to apply, mechanical forces or chemicals such as detergents to the surface to remove foreign matter such as dirt. As the coatings are amphiphobic, they are able to repel both water-based and oil-based substances. Accordingly, coatings disclosed herein may keep surfaces cleaner for a longer period of time. Furthermore, contaminants such as fingerprint, skin oil residue, and dust particles may not attach to surfaces comprising the coatings. As such, the coatings may be anti-fingerprint.

In addition to or apart from the self-cleaning and anti-fingerprint properties, coatings disclosed herein are able to provide good light transmittance and anti-reflection properties. As demonstrated from experiments carried out, amphiphobic coatings disclosed herein may exhibit a transmittance of at least 84% in the wavelength region from 400 nm to 700 nm. Coatings disclosed herein are also able to adhere well to polymeric substrates, thereby providing mechanical robustness and durability for long term usage. Methods of preparing the amphiphobic coating may be carried out at ambient conditions or room temperature, which render the methods particularly suited for preparing amphiphobic coatings on polymeric substrates which are heat sensitive or with low melting points towards a wider range of functional surface applications.

With the above in mind, the amphiphobic coating according to various embodiments comprises a polymeric substrate having an oxygen plasma-treated surface; a silicon dioxide layer comprising silicon dioxide nanoparticles disposed directly on the oxygen plasma-treated surface; and a fluoroalkylsilane layer disposed directly on the silicon dioxide layer.

The polymeric substrate may be any suitable polymeric materials. Material for the polymeric substrate may, for example, be selected from the group consisting of polycarbonate, poly (methyl methacrylate), polyester, polyethylene terephthalate, polyimide, polytetrafluoroethylene, polypropylene, polyolefin, Nylon, silicone, polyvinyl chloride, polystyrene, and polyphenylene sulfide. Composites of these materials may also be used as the substrate.

In specific embodiments, material for the polymeric substrate is polycarbonate.

Shape and structure of the polymeric substrate may be arbitrarily selected, and is not limited to a planar surface. For example, the polymeric substrate may have a non-planar shape or other sophisticated shapes, or be in the form of a product or an article of manufacture having a surface onto which the coating is to be applied.

In various embodiments, the polymeric substrate has an oxygen plasma-treated surface. Advantageously, action of oxygen plasma on the polymeric substrate may result in increased surface roughness. Surface structures with re-entrant topography may be formed. The term “re-entrant” is used to describe topography of a structure formed beneath a substrate surface and having an opening at the substrate surface, whereby width of a cross-section of the structure is larger as distance away from the opening increases. Formation of the surface structures with re-entrant topography may advantageously result in increase of contact angles with a water-based substance and an oil-based substance. In addition, there may be altered surface chemistry with more oxygen bonding on the surface. This increases surface energy of the polymer substrate, and may be used to enhance stability and adhesion with subsequently deposited coatings.

In various embodiments, a silicon dioxide layer comprising silicon dioxide nanoparticles is disposed directly on the oxygen plasma-treated surface of the polymeric substrate. By the term “directly”, this means that the silicon dioxide layer is in contact with the oxygen plasma-treated surface of the polymeric substrate. In other words, an intermediate layer between the silicon dioxide layer and the oxygen plasma-treated surface of the polymeric substrate may not be present.

In various embodiments, the silicon dioxide is disposed directly in the form of nanoparticles on the oxygen plasma-treated surface of the polymeric substrate. The silicon dioxide layer may comprise or consist of silicon dioxide nanoparticles. The silicon dioxide nanoparticles may have an average size in the range from 25 nm to 50 nm, such as 30 nm to 50 nm, 40 nm to 50 nm, 25 nm to 40 nm, 25 nm to 30 nm, or 30 nm to 40 nm.

The silicon dioxide nanoparticles may be uniformly distributed or dispersed on the oxygen plasma-treated surface of the polymeric substrate. In various embodiments, the silicon dioxide nanoparticles form clusters having a size in the range from 150 nm to 250 nm, such as 160 nm to 250 nm, 170 nm to 250 nm, 180 nm to 250 nm, 190 nm to 250 nm, 200 nm to 250 nm, 150 nm to 240 nm, 150 nm to 230 nm, 150 nm to 220 nm, 150 nm to 200 nm, or 180 nm to 200 nm.

The silicon dioxide nanoparticles may coalesce to form a porous layer. In various embodiments, the silicon dioxide layer is nanoporous. Porosity of the silicon dioxide layer may result in the amphiphobic coating having a certain surface roughness factor.

Roughness factor R_{f} of the amphiphobic coating may be in the range of 0.1 to 0.5, such as 0.15 to 0.5, 0.2 to 0.5, 0.25 to 0.5, 0.3 to 0.5, 0.1 to 0.45, 0.1 to 0.4, 0.1 to 0.35, 0.1 to 0.3, 0.15 to 0.45, 0.15 to 0.4, 0.2 to 0.3, 0.22 to 0.26, or 0.24 to 0.25. In various embodiments, roughness factor R_{f} of the amphiphobic coating is 0.2451 or less, such as 0.24 or less, 0.23 or less, 0.22 or less, 0.21 or less, or 0.2 or less. Advantageously, this may confer amphiphobicity to or result in good amphiphobicity of the amphiphobic coating.

The silicon dioxide layer may have a thickness in the range from 10 nm to 500 nm, such as 20 nm to 500 nm, 30 nm to 500 nm, 50 nm to 500 nm, 75 nm to 500 nm, 100 nm to 500 nm, 200 nm to 500 nm, 300 nm to 500 nm, 400 nm to 500 nm, 10 nm to 400 nm, 10 nm to 300 nm, 10 nm to 200 nm, 10 nm to 100 nm, 20 nm to 400 nm, 30 nm to 300 nm, 10 nm to 150 nm, or 50 nm to 100 nm.

The silicon dioxide layer may be crystalline, non-crystalline or a mixed phase of crystalline and non-crystalline. In various embodiments, the silicon dioxide layer is non-crystalline.

In various embodiments, a fluoroalkylsilane layer is disposed directly on the silicon dioxide layer. By the term “directly”, this means that the silicon dioxide layer is in contact with the fluoroalkylsilane layer. In other words, an intermediate layer between the silicon dioxide layer and the fluoroalkylsilane layer may not be present. Generally, fluoroalkylsilanes which are able to provide fluorocarbon molecules on surface resulting in lower surface energy for amphobicity may be used. In so doing, an amphiphobic coating with excellent anti-reflection, anti-fingerprint, and self-cleaning properties may be obtained.

The fluoroalkylsilane layer may, for example, be formed from a fluoroalkylsilane selected from the group consisting of trichloro (1H,1H,2H,2H-perfluorooctyl) silane, 1H,1H,2H,2H perfluorodecyltriethoxysilane, and combinations thereof. In some embodiments, the fluoroalkylsilane layer is formed from trichloro (1H,1H,2H,2H-perfluorooctyl) silane.

In various embodiments, surface of the silicon dioxide layer comprises hydroxyl groups. The hydroxyl groups on the silicon dioxide layer may result from methods used to deposit the silicon dioxide layer. For example, pulsed laser deposition may be used to deposit the silicon dioxide layer, and in so doing, generate hydroxyl groups on the surface. The fluoroalkylsilane layer disposed directly on the silicon dioxide layer may be covalently bonded to the silicon dioxide layer via the hydroxyl groups.

In various embodiments, the fluoroalkylsilane layer is a self-assembled layer. As used herein, the terms “self-assembled” or “self-assembly” refer to spontaneous organisation or arrangement of a compound on a surface, which may be affected or influenced by affinity of the compound with moieties which may be present on the underlying surface. In embodiments whereby surface of the silicon dioxide layer comprises hydroxyl groups, for example, the fluoroalkylsilane molecules may self-assemble on the silicon dioxide layer and be covalently bonded to the hydroxyl groups present on the silicon dioxide layer.

The coatings disclosed herein may be formed from a single silicon dioxide layer comprising silicon dioxide nanoparticles, and a single fluoroalkylsilane layer. The single silicon dioxide layer may be formed of a single layer of silicon dioxide nanoparticles. Accordingly, in some embodiments, coatings disclosed herein are made up from only two layers on the polymeric substrate. This may be advantageous in terms of improved processing efficiency and reduced costs in forming an amphiphobic coating with only two layers. In some embodiments, the silicon dioxide layer comprising silicon dioxide nanoparticles may have a multi-layer structure comprising or consisting of multiple layers of silicon dioxide nanoparticles. Multiple layers of the silicon dioxide nanoparticles may be used, such as two, three, four, five, six, seven, or more layers. For example, the coatings disclosed herein may comprise a silicon dioxide layer comprising two or more layers of silicon dioxide nanoparticles, and a single fluoroalkylsilane layer. In embodiments wherein multi-layers of the silicon dioxide nanoparticles are used, a topmost surface of the silicon dioxide layer may have surface roughness and surface features as disclosed herein, and/or which are the same as or similar to that formed from a silicon dioxide layer comprising a single layer of silicon dioxide nanoparticles, such that when a fluoroalkylsilane layer is disposed directly thereon, an amphiphobic coating disclosed herein may be obtained.

The amphiphobic coating as disclosed herein may exhibit a transmittance of at least 84% in the wavelength region from 400 nm to 700 nm. For example, the amphiphobic coating may have a transmittance of at least 85%, at least 86%, at least 87%, at least 88%, at least 89% or at least 90% in the wavelength region from 400 nm to 700 nm. In some embodiments, the amphiphobic coating may have a transmittance of up to 92%. Accordingly, the amphiphobic coating may have a transmittance in the range from 85% to 92%, 87% to 92%, 89% to 92%, 85% to 90%, 85% to 88%, or 86% to 90%.

As mentioned above, the amphiphobic coating disclosed herein may be superhydrophobic and highly oleophobic. Contact angle of water on the amphiphobic coating may be more than 150°, such as more than 151°, more than 152°, more than 153°, more than 154°, or more than 155°. In various embodiments, contact angle of diiodomethane on the amphiphobic coating is more than 130°, such as more than 131°, more than 132°, more than 133°, more than 134°, or more than 135°. As will be appreciated by a person skilled in the art, a different contact angle range for the amphiphobic coating may be established if another oil or oil-based fluid is used for contact angle measurement.

Various embodiments refer in a second aspect to a method of preparing an amphiphobic coating.

The method may comprise providing a polymeric substrate having an oxygen plasma-treated surface. As mentioned above, action of oxygen plasma on the polymeric substrate may result in increased surface roughness and generation of oxygen bonding on the surface. This increases surface energy of the polymer substrate, and may be used to enhance adhesion with subsequently deposited coatings.

In various embodiments, providing a polymeric substrate having an oxygen plasma-treated surface comprises treating a surface of the polymeric substrate with an oxygen-containing plasma.

Treating the surface of the polymeric substrate with an oxygen-containing plasma may be carried out for any suitable time depending, for example, on the flow rate and/or type oxygen-containing plasma used, as well as area to be treated. In various embodiments, treating a surface of the polymeric substrate with an oxygen-containing plasma may be carried out for a time period in the range from 10 minutes to 20 minutes, such as 12 minutes to 20 minutes, 14 minutes to 20 minutes, 15 minutes to 20 minutes, 10 minutes to 18 minutes, 10 minutes to 15 minutes, 12 minutes to 18 minutes, or 14 minutes to 16 minutes.

Treating a surface of the polymeric substrate with an oxygen-containing plasma may be carried out at a pressure in the range from 10⁻³ mbar to 10⁻¹ mbar, such as 10⁻³ mbar to 10⁻² mbar or 10⁻² mbar to 10⁻¹ mbar. In some embodiments, treating a surface of the polymeric substrate with an oxygen-containing plasma is carried out at a pressure in the range from 10⁻³ mbar to 10⁻² mbar.

In various embodiments, treating a surface of the polymeric substrate with an oxygen-containing plasma further comprises cleaning a surface of the polymeric substrate with an alcohol and denionized water prior to treating the surface with the oxygen-containing plasma. Advantageously, this helps to ensure removal of contaminants that may be present on the polymeric substrate surface prior to oxygen plasma treatment, so as to enhance adhesion of coatings on the polymeric substrate.

Methods disclosed herein may comprise depositing silicon dioxide directly on the oxygen plasma-treated surface of the polymeric substrate by pulsed laser deposition to form a silicon dioxide layer comprising silicon dioxide nanoparticles, and depositing a fluoroalkylsilane directly on the silicon dioxide layer to form a fluoroalkylsilane layer on the silicon dioxide layer. By the term “directly”, this means that the silicon dioxide layer is in contact with the oxygen plasma-treated surface of the polymeric substrate, while the fluoroalkylsilane layer is in contact with the silicon dioxide layer.

For depositing silicon dioxide directly on the oxygen plasma-treated surface of the polymeric substrate, targets containing silicon or silicon dioxide may be used.

In some embodiments, a silicon target is used. Accordingly, depositing silicon dioxide directly on the oxygen plasma-treated surface of the polymeric substrate may comprise providing a silicon target, and directing a pulsed laser beam at the silicon target in the presence of oxygen to generate silicon plasma which interacts with the background oxygen plasma to form the silicon dioxide layer on the oxygen plasma-treated surface of the polymeric substrate. The background oxygen plasma may be oxygen plasma that is generated due to action of pulsed laser beam on the oxygen that is present, and/or due to interaction of ablated silicon plasma with the oxygen that is present. For interaction of ablated silicon plasma with the oxygen that is present, collision and charge exchange between the ablated energetic silicon plasma species and background oxygen may create oxygen plasma and active oxygen species which interact with silicon plasma to form oxides of silicon.

In some embodiments, a silicon dioxide target is used. Accordingly, depositing silicon dioxide directly on the oxygen plasma-treated surface of the polymeric substrate may comprise providing a silicon dioxide target, and directing a pulsed laser beam at the silicon dioxide target to form the silicon dioxide layer on the oxygen plasma-treated surface of the polymeric substrate.

Oxygen may not be required when a silicon dioxide target is used, as pulsed laser deposition may reproduce stoichiometry of the target on the polymeric substrate. The respective process may nevertheless be carried out in the presence of oxygen, however, so as to prevent or avoid oxygen deficiencies in the silicon dioxide layer that is being formed. Accordingly, in various embodiments, depositing silicon dioxide directly on the oxygen plasma-treated surface of the polymeric substrate may be carried out in the presence of oxygen, regardless of whether silicon or silicon dioxide are being used as targets to form the silicon dioxide layer.

In some embodiments, depositing of the silicon dioxide may be carried out in a chamber in the presence of oxygen, and the oxygen may be introduced to the chamber at a flow rate in the range from 100 sccm to 300 sccm, 120 sccm to 300 sccm, 150 sccm to 300 sccm, 200 sccm to 300 sccm, 250 sccm to 300 sccm, 100 sccm to 250 sccm, 100 sccm to 200 sccm, 150 sccm to 250 sccm, or 180 sccm to 220 sccm.

The respective targets of silicon and silicon dioxide may be independently spaced apart from the polymeric substrate at a distance in the range from 3 cm to 8 cm, such as 5 cm to 8 cm, 6 cm to 8 cm, 3 cm to 7 cm, 3 cm to 5 cm, 4 cm to 7 cm, or 4 cm to 6 cm. By the term “independently spaced apart”, this means that the respective targets may be spaced at the same or at a different distance away from the polymeric substrate.

In some embodiments, a silicon target is used to form the silicon dioxide layer. The silicon target may be spaced apart from the polymeric substrate at a distance of 4 cm to 6 cm, such as about 5 cm.

In applying pulsed laser to the silicon or silicon dioxide target to deposit the silicon dioxide layer, high energy hydroxyl groups may be conferred to the formed layer. The silicon dioxide may be deposited in the form of nanoparticles. A single layer or multiple layers of the silicon dioxide nanoparticles may be formed. In some embodiments, the nanoparticles may coalesce upon further application of the pulsed laser to result in formation of porous layers.

The pulsed laser beam may form a spot size of 3×10⁻⁴ cm² to 7×104 cm² on the silicon target or the silicon dioxide target. In various embodiments, the pulsed laser beam may form a spot size of 4×10⁻⁴ cm² to 7×104 cm², 5×10⁻⁴ cm² to 7×104 cm², 6×10⁻⁴ cm² to 7×10⁻⁴ cm², 4×10⁻⁴ cm² to 6×10⁻⁴ cm² or 5×10⁻⁴ cm² to 6×104 cm² on the respective targets. In specific embodiments, pulsed laser beam may form a spot size of 4×10⁻⁴ cm² to 6×10⁻⁴ cm² on the respective targets.

In various embodiments, the pulsed laser beam has a wavelength of about 532 nm.

In various embodiments, the pulsed laser beam has a frequency in the range from 8 Hz to 12 Hz, such as 9 Hz to 12 Hz, 10 Hz to 12 Hz, 8 Hz to 11 Hz, 8 Hz to 10 Hz, or 9 Hz to 11 Hz. In some embodiments, the pulsed laser beam has a frequency in the range from 9 Hz to 11 Hz.

The pulsed laser beam may have a fluence in the range from 1 Jcm⁻² to 10 Jcm⁻². For example, the pulsed laser beam may have a fluence in the range from 2 Jcm⁻² to 10 Jcm⁻², 3 Jcm⁻² to 10 Jcm⁻², 4 Jcm⁻² to 10 Jcm⁻², 2 Jcm⁻² to 8 Jcm⁻², 2 Jcm⁻² to 6 Jcm⁻², 2 Jcm⁻² to 5 Jcm⁻², 3 Jcm⁻² to 8 Jcm⁻², or 4 Jcm⁻² to 5 Jcm⁻². In some embodiments, the pulsed laser beam has a fluence in the range from 4 Jcm⁻² to 5 Jcm⁻².

Time period for depositing the silicon dioxide may depend on thickness of the silicon dioxide layer to be formed. In various embodiments, depositing the silicon dioxide is carried out for a time period in the range from 30 minutes to 90 minutes, such as 40 minutes to 90 minutes, 50 minutes to 90 minutes, 60 minutes to 90 minutes, 70 minutes to 90 minutes, 30 minutes to 80 minutes, 30 minutes to 70 minutes, 30 minutes to 60 minutes, 30 minutes to 50 minutes, 40 minutes to 80 minutes, 50 minutes to 70 minutes, or 60 minutes.

As mentioned above, the polymeric substrate may be any suitable polymeric materials. Material for the polymeric substrate may, for example, be selected from the group consisting of polycarbonate, poly (methyl methacrylate), polyester, polyethylene terephthalate, polyimide, polytetrafluoroethylene, polypropylene, polyolefin, Nylon, silicone, polyvinyl chloride, polystyrene, and polyphenylene sulfide. Composites of these materials may also be used as the substrate.

In various embodiments the polymeric substrate is polycarbonate.

Shape and structure of the polymeric substrate may be arbitrarily selected, and is not limited to a planar surface. For example, the polymeric substrate may have a non-planar shape or any sophisticated shapes, or be in the form of a product or an article of manufacture having a surface onto which the coating is to be applied.

As mentioned above, any fluoroalkylsilane which is able to provide fluorocarbon molecules on surface resulting in lower surface energy for amphobicity may be used. In various embodiments, the fluoroalkylsilane layer is formed from a fluoroalkylsilane selected from the group consisting of trichloro (1H,1H,2H,2H-perfluorooctyl) silane, 1H,1H,2H,2H perfluorodecyltriethoxysilane, and combinations thereof.

In various embodiments, depositing a fluoroalkylsilane directly on the silicon dioxide layer comprises contacting the silicon dioxide layer with a solution comprising the fluoroalkylsilane and a liquid reagent. The liquid reagent may function as a solvent, and may be selected from the group consisting of hexane and methanol.

Concentration of the fluoroalkylsilane in the solution may be in the range from 0.05 vol % to 0.15 vol %, such as 0.06 vol % to 0.15 vol %, 0.07 vol % to 0.15 vol %, 0.08 vol % to 0.15 vol %, 0.09 vol % to 0.15 vol %, 0.1 vol % to 0.15 vol %, 0.05 vol % to 0.14 vol %, 0.05 vol % to 0.13 vol %, 0.05 vol % to 0.12 vol %, 0.05 vol % to 0.11 vol %, 0.05 vol % to 0.1 vol %, or 0.08 vol % to 0.12 vol %.

Contacting the silicon dioxide layer with the solution may be carried out for any suitable time period, such as a time period in the range of 5 minutes to 20 minutes, 8 minutes to 20 minutes, 10 minutes to 20 minutes, 12 minutes to 20 minutes, 5 minutes to 18 minutes, 5 minutes to 15 minutes, or 8 minutes to 15 minutes.

In various embodiments, the method disclosed herein may be carried out without heating. For example, deposition of the silicon dioxide layer and the fluoroalkylsilane may be carried out without heating. In some embodiments, the method is carried out at ambient conditions or room temperature, such as a temperature in the range of about 20° C. to 45° C., or about 25° C. to 35° C.

In various embodiments, depositing a fluoroalkylsilane directly on the silicon dioxide layer further comprises drying the silicon dioxide layer after it has contacted with the solution.

Even though drying of the silicon dioxide layer may be possible without heating, heating may be applied to expedite on drying. In various embodiments, the drying is carried out at a temperature in the range from 70° C. to 90° C., such as 75° C. to 90° C., 80° C. to 90° C., 85° C. to 90° C., 70° C. to 85° C., 70° C. to 80° C., 70° C. to 75° C., or 75° C. to 85° C.

The drying may be carried out for any suitable time period. When heating is applied, the drying may be carried for a time period in the range from 1 hour to 3 hours, 1.5 hour to 3 hours, 2 hours to 3 hours, 1 hour to 2.5 hours, 1 hour to 2 hours, or 1.5 hour to 2.5 hours.

Various embodiments refer in a third aspect to an amphiphobic coating prepared by a method according to the second aspect.

As mentioned above, methods disclosed herein may advantageously be used to prepare amphiphobic coatings which are capable of self-cleaning and having anti-fingerprint and anti-reflection properties. By applying oxygen plasma on a polymeric substrate surface, there may be increased surface roughness with formation of structures having re-entrant topography. As a result, contact angles with a water-based substance and an oil-based substance may be increased. In addition, surface energy of the polymer substrate may be increased to enhance adhesion with the silicon dioxide layer deposited thereon. By using pulsed laser deposition to deposit the silicon dioxide layer, hydroxyl groups may be generated on the silicon dioxide layer. Treatment of the silicon dioxide layer with fluoroalkylsilane may result in covalent bonding of the fluoroalkylsilane to the silicon dioxide layer. The fluoroalkylsilane may form a fluoroalkylsilane layer on the silicon dioxide layer. This may translate into lower surface energy for amphobicity of the resultant coating. An amphiphobic coating with excellent anti-reflection, anti-fingerprint, and self-cleaning properties may be obtained.

Various embodiments refer in a fourth aspect to use of an amphiphobic coating according to the first aspect or an amphiphobic coating prepared by a method according to the second aspect in anti-reflection coatings, anti-fingerprint coatings, anti-fouling coatings, self-cleaning surfaces, primer layer for surfaces, optical components, sensors, lens, goggles, mirrors, windshields, face shields, displays, windows, or cookware covers.

As mentioned above, the amphiphobic coating disclosed herein may be hydrophobic as well as oleophobic. Coatings according to embodiments disclosed herein are capable of exhibiting self-cleaning, anti-fingerprint and/or anti-reflection properties. As methods for preparing the coatings may be carried out at ambient conditions, they are particularly suited for preparing amphiphobic coatings on polymeric substrates which are heat sensitive or with low melting points.

Various embodiments refer in a fifth aspect to an article of manufacture comprising an amphiphobic coating according to the first aspect or an amphiphobic coating prepared by a method according to the second aspect, wherein the article is an optical component, sensor, lens, goggles, mirror, windshield, face shield, display, window, or cookware covers.

In order that the invention may be readily understood and put into practical effect, particular embodiments will now be described by way of the following non-limiting examples.

### EXAMPLES

According to embodiments disclosed herein, a facile and effective fabrication method to prepare highly transparent amphiphobic coating on polycarbonate (PC) with superhydrophobicity and high oleophobicity is provided.

In an experiment carried out, nanoporous thin film comprising silicon dioxide (SiO₂) nanoparticles was deposited via pulsed laser deposition on a polycarbonate (PC) that was pretreated with oxygen plasma. The deposition may be carried out at ambient temperature and pressure. After the thin film was deposited, trichloro (1H,1H,2H,2H-perfluorooctyl) silane (PFTS) was assembled on the silica surface. The as-prepared PFTS-treated silica coating demonstrated amphiphobicity, in that it was superhydrophobic with water contact angle at 155.2±1.8° and highly oleophobic with contact angle of 133.6±3.3° with diiodomethane. The coating also displayed excellent adhesion with the PC substrate. The developed room temperature deposition process makes it potentially applicable in modification of temperature-sensitive and other low melting point polymeric substrates towards a wider range of functional surface applications. The as-prepared coating demonstrated excellent anti-reflection, anti-fingerprint, and self-cleaning properties after its surface is decorated with a fluorocarbon compound. Mechanically, the coating exhibited good stability and strong adhesion to the polymer substrate due to the pre-deposition plasma treatment.

### Example 1: Sample Preparation

### Example 1.1: Coating of Silica Nanoparticle Film

Coating of silica nanoparticle film was performed through a two-step process. Polycarbonate (PC) substrate (size of 1.5 cm×1.5 cm) was cleaned with ethanol and deionized water for a few cycles prior to the coating. A surface oxygen plasma treatment was carried out before deposition of the silica nanoparticle film. Solution-cleaned PC substrate was placed inside a radio frequency (RF) plasma tube chamber, which was capacitively coupled with two ring electrodes mounted outside the tube. The chamber was evacuated to a base pressure at 10⁻³ mbar through vacuum pump, and then stabilized at 10⁻² mbar after oxygen gas was supplied into the chamber at flow rate of 2 sccm. Oxygen plasma was activated with 250 W RF power supplied by a 13.56 MHz caeser 136 RF generator with an auto-impedance matching unit. The oxygen plasma surface treatment was carried out for 15 min.

Silica nanoparticle film was deposited through a pulse laser deposition (PLD) system in the second step. Silicon target (purchased from S1-Lab Pte Ltd, 99.99%) and the plasma treated PC substrate was placed 5 cm away and facing each other in the deposition chamber. The system was evacuated to 10⁻⁵ mbar, and oxygen gas was then introduced into the chamber at a flow rate of 200 sccm, resulting in a stable chamber pressure of 10⁻² mbar. Nd:YAG 532 nm laser that was operated at 10 Hz with laser pulse fluence of F=4.74 Jcm⁻² focused on the silicon target at a spot size around 5.0×10⁻⁴ cm². The deposition process was carried out for 4 different deposition duration: 10 min, 30 min, 60 min and 90 min.

### Example 1.2: Decoration of Trichloro (1H,1H,2H,2H-perfluorooctyl) silane

Trichloro (1H,1H,2H,2H-perfluorooctyl) silane (PFTS) (CF₃(CF₂)₅CH₂CH₂SiCl₃) was purchased from Sigma Aldrich. The as-prepared silica nanoparticle film was immersed in a 0.1 vol % PFTS in hexane solution for 10 min. The sample was then placed in a drying cabinet at 80° C. for 2 h.

### Example 2: Material Characterization

JEOL 7600 field emission scanning electron microscope (SEM) was used and operated at 2.0 kV to observe surface morphology. NX10 Park system atomic force microscope (AFM) was used to examine the surface topology as well as to measure surface roughness parameters. Kratos AXIS Supra X-ray Photoelectron Spectrometer (XPS) was used for surface chemical composition analysis. For reference, the binding energy of C 1s peak from sp2-bonded carbon at 284.8 eV was used. Additional surface chemical molecular bonding analysis was performed using Fourier Transformation Infra-Red (FTIR) spectrometer (Perkin Elmer Frontier). A contact angle goniometer (OCA 20 Dataphysic) was used to record static water contact angle (WCA) and oil (using diiodomethane as an example) contact angle (OCA) with 5 μL DI water droplet and 3 μL oil droplet, respectively. A Perkin Elmer Lambda 950 UV-VIS-NIR spectrometer was employed to measure the light transmittance in the visible light wavelength range.

### Example 3: Mechanical Durability

### Example 3.1: Abrasion Test (MIL-C-48497 Standard)

Surface was rubbed with a cheese cloth pad at a constant force (400-gram weight uniformly distributed on 1.5 cm×1.5 cm substrates, which corresponds to 26.7 kPa pressure). Rubbing action was applied for 20 times (20 strokes) in each test. Observation under SEM as well as naked eye was carried out after the test to monitor the surface condition.

### Example 3.2: Adhesion Test (MIL-C-48497 Standard)

A cellophane tape was pressed onto the coating surface first and was then pulled off very slowly at an angle of 45°. Observation under SEM as well as naked eye was carried out after the test.

### Example 3.3: Adhesion Test (ASTM-3359 Standard)

A sharp steel cutter was used to crosscut the coating surface. Cellophane tape was pressed onto the surface and then slowly pulled off from the surface. Observation under SEM as well as naked eye was carried out after the test to assess the coating performance.

### Example 4: Results and Discussion

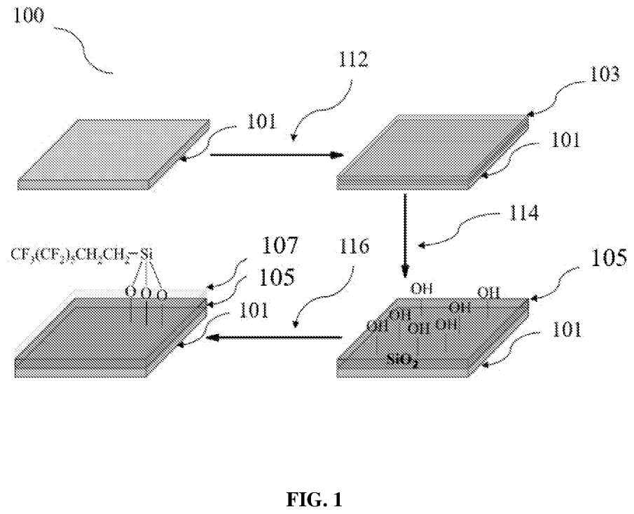

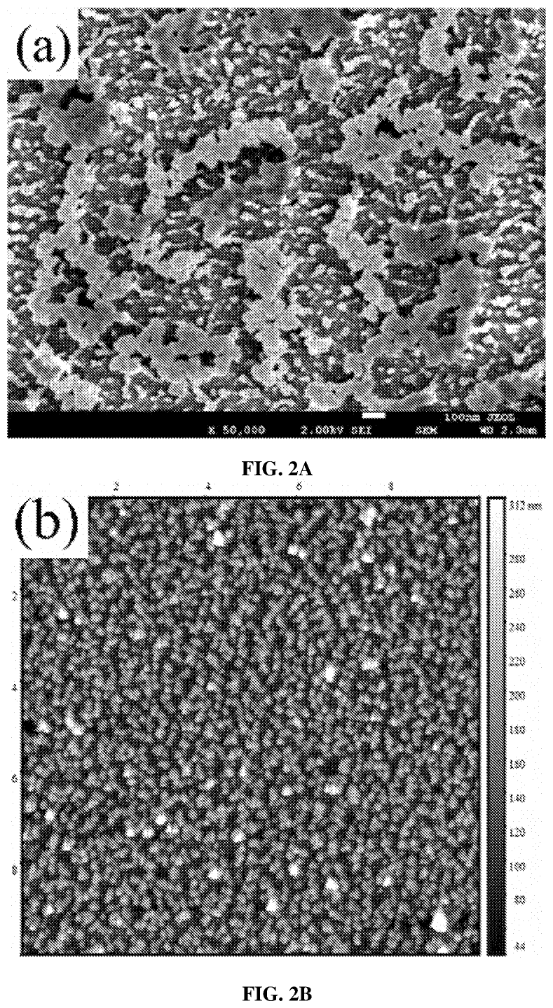

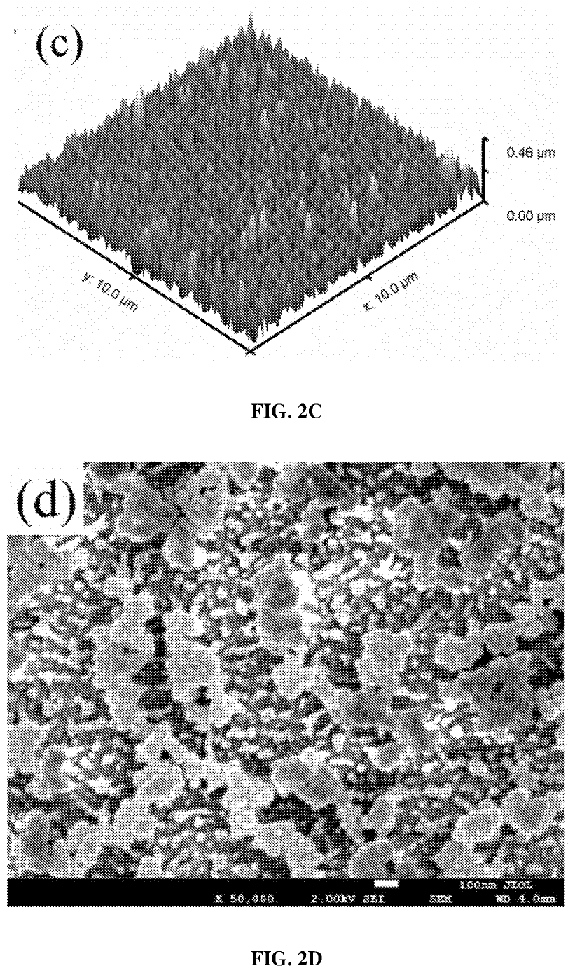

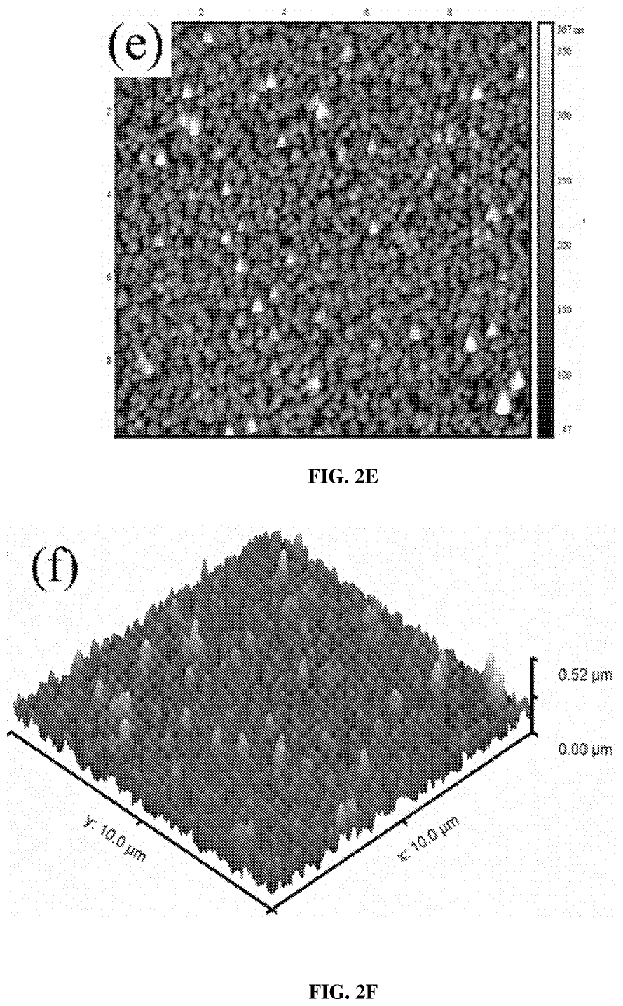

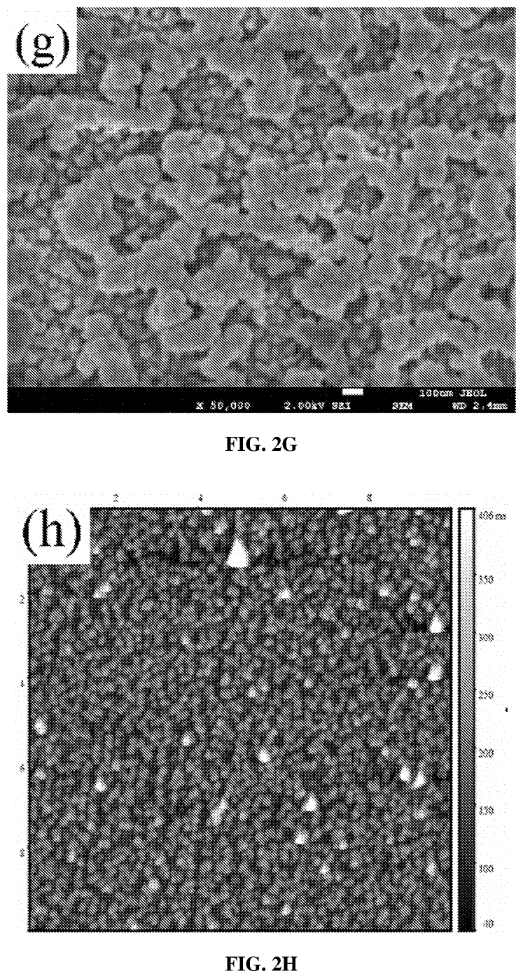

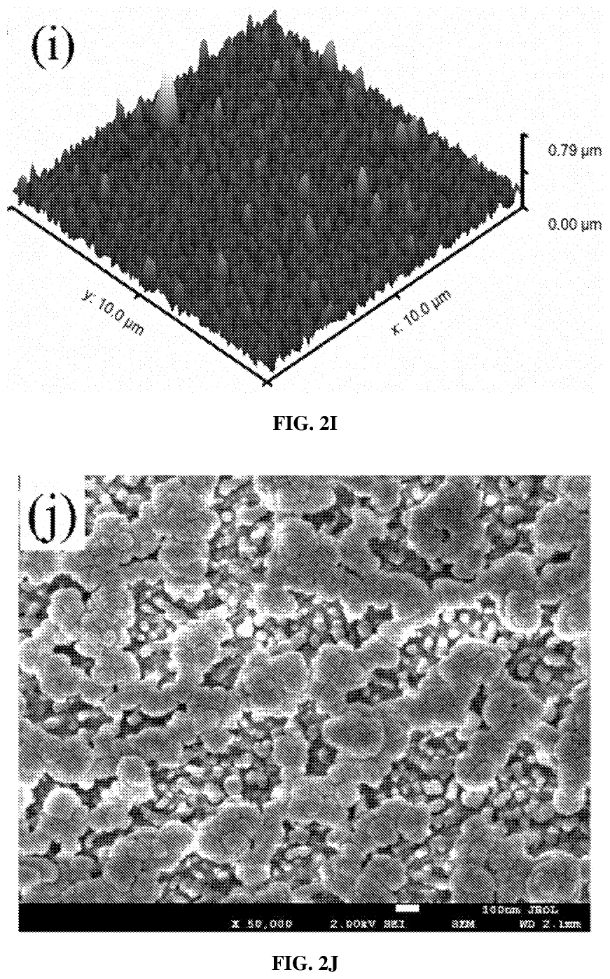

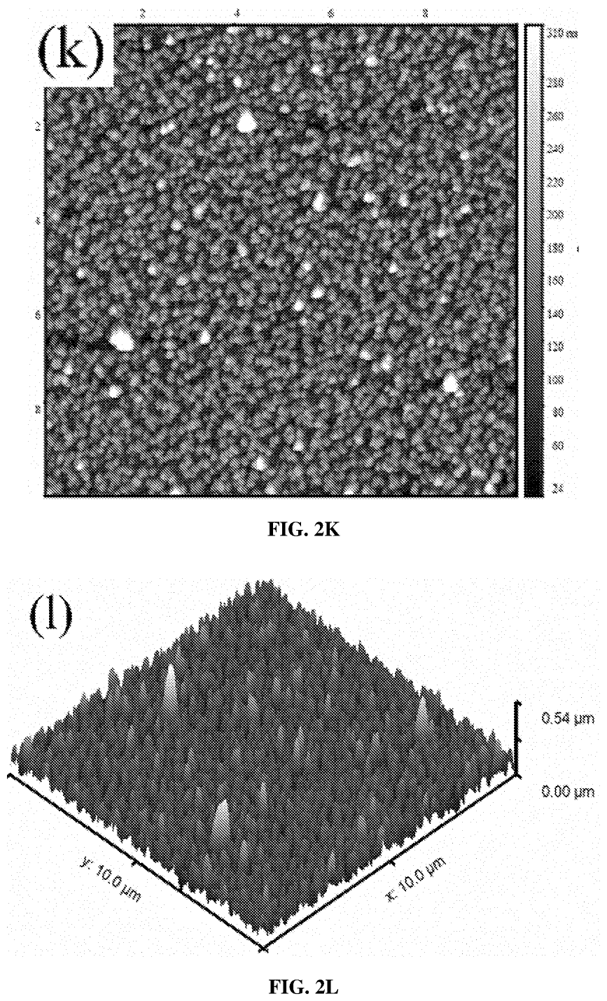

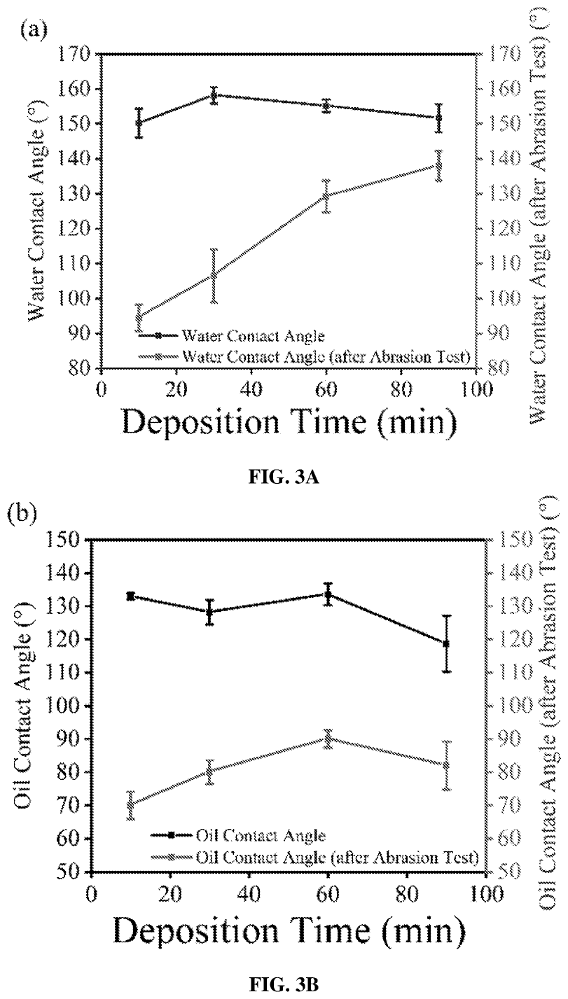

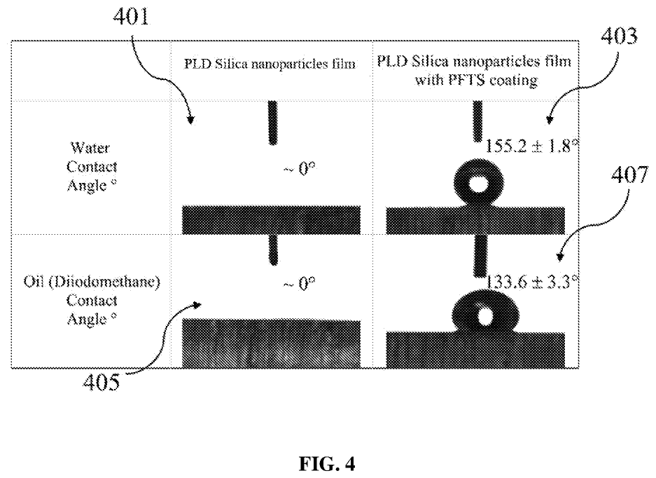

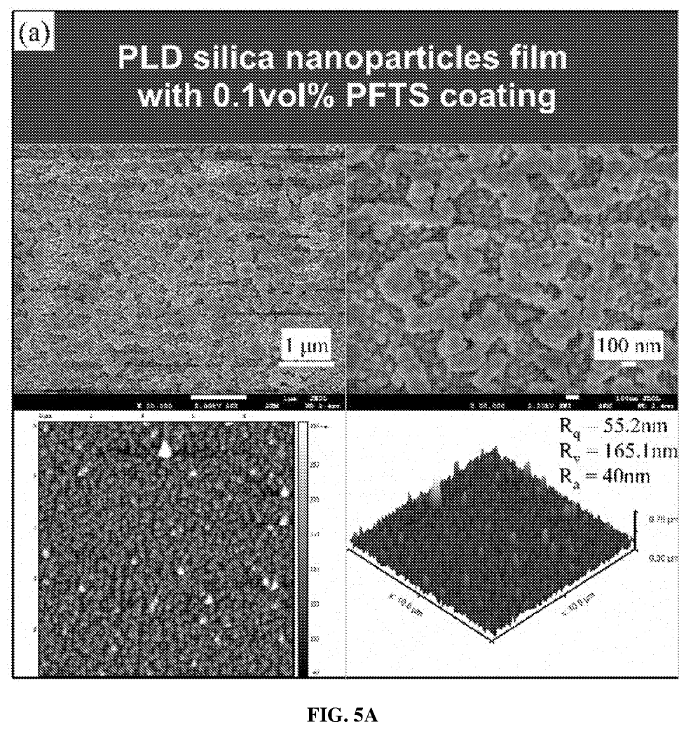

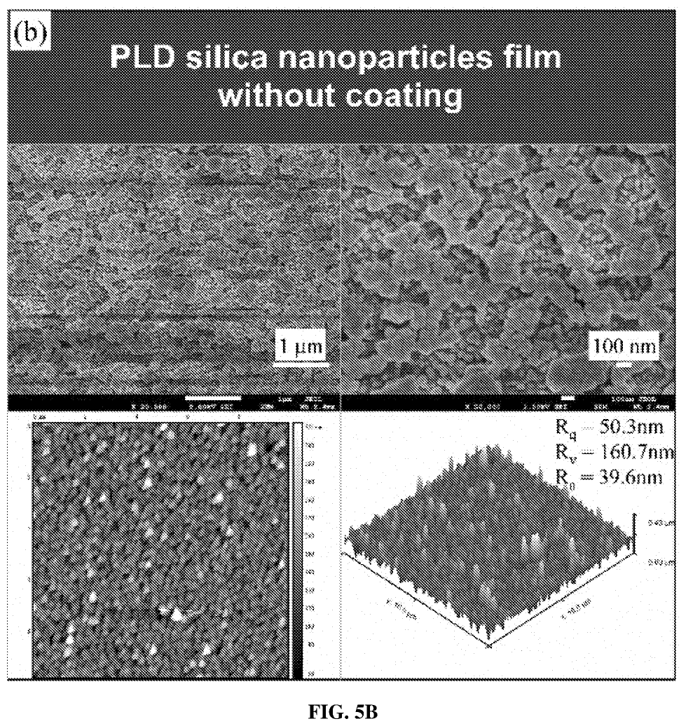

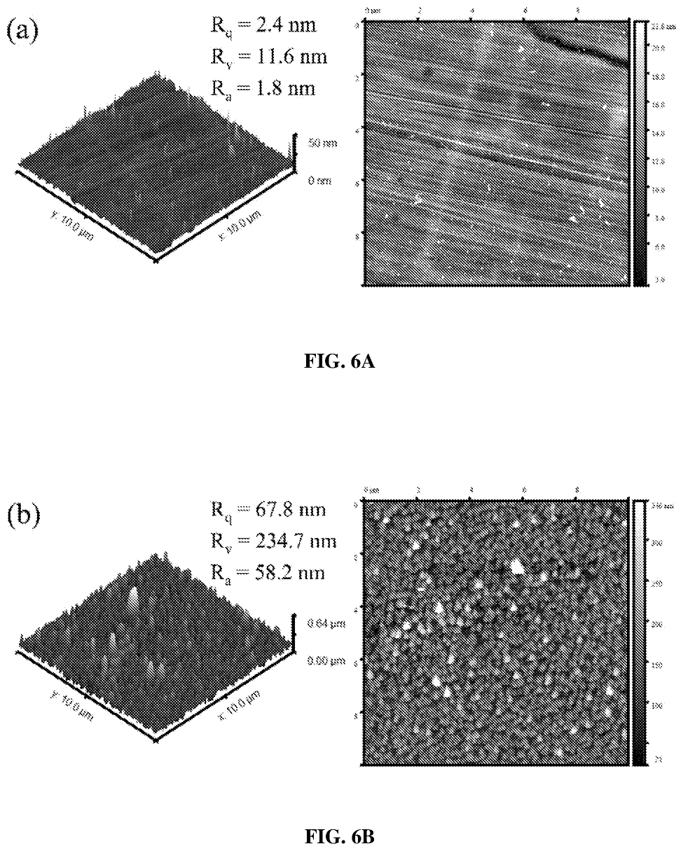

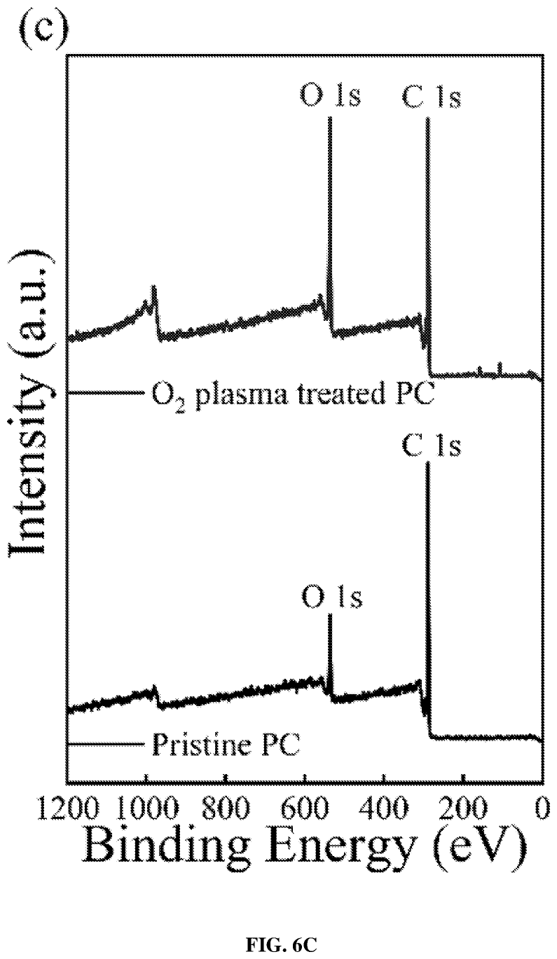

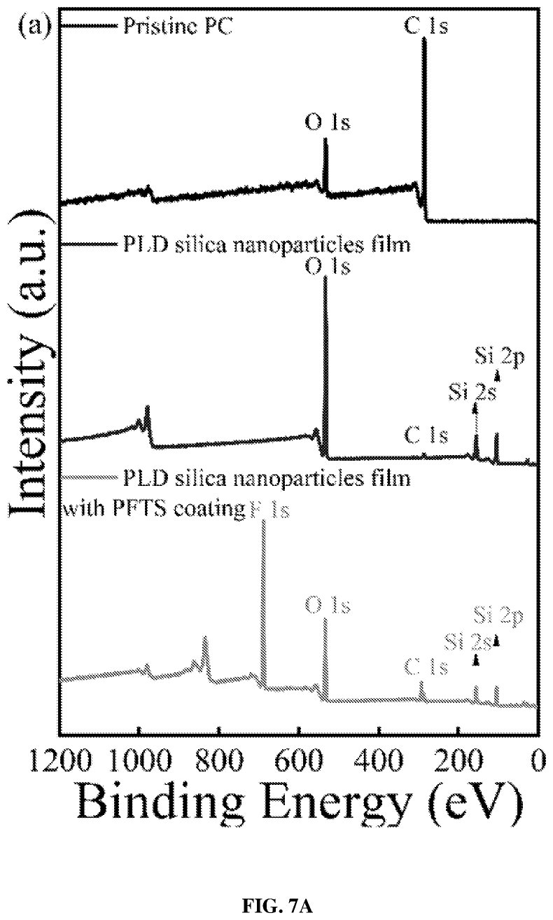

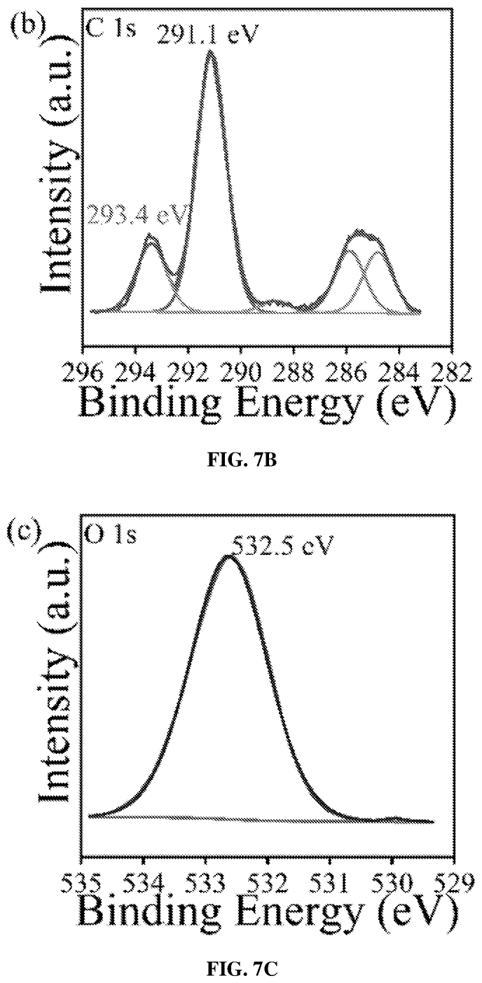

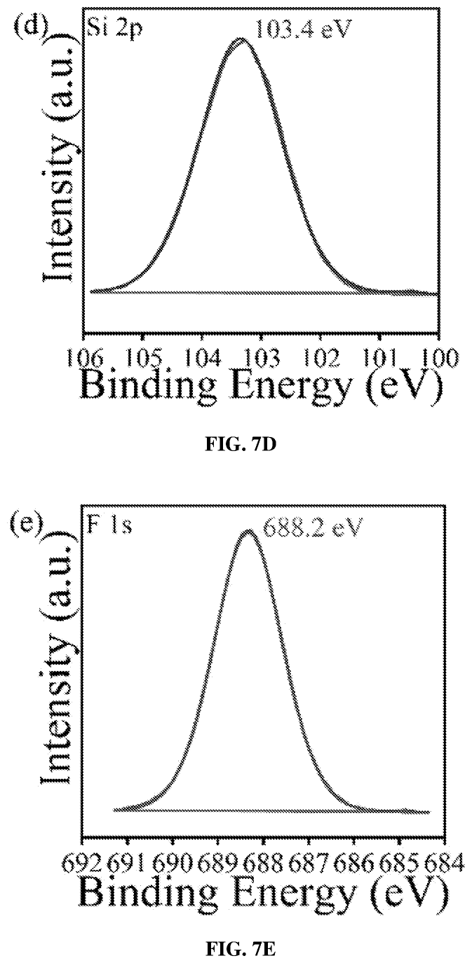

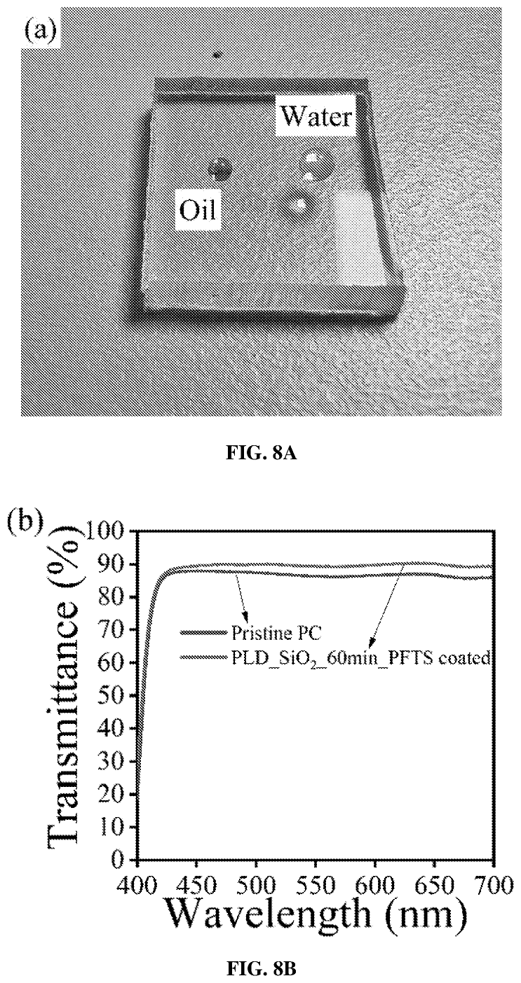

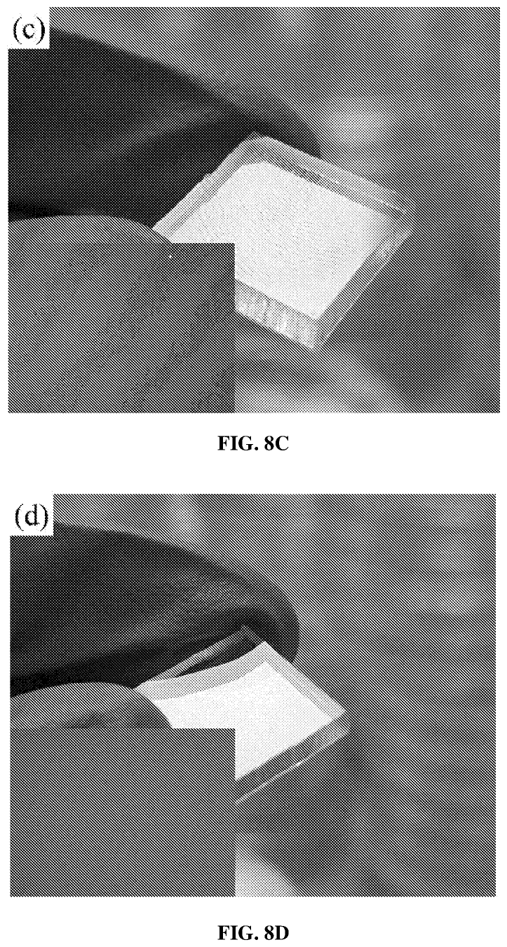

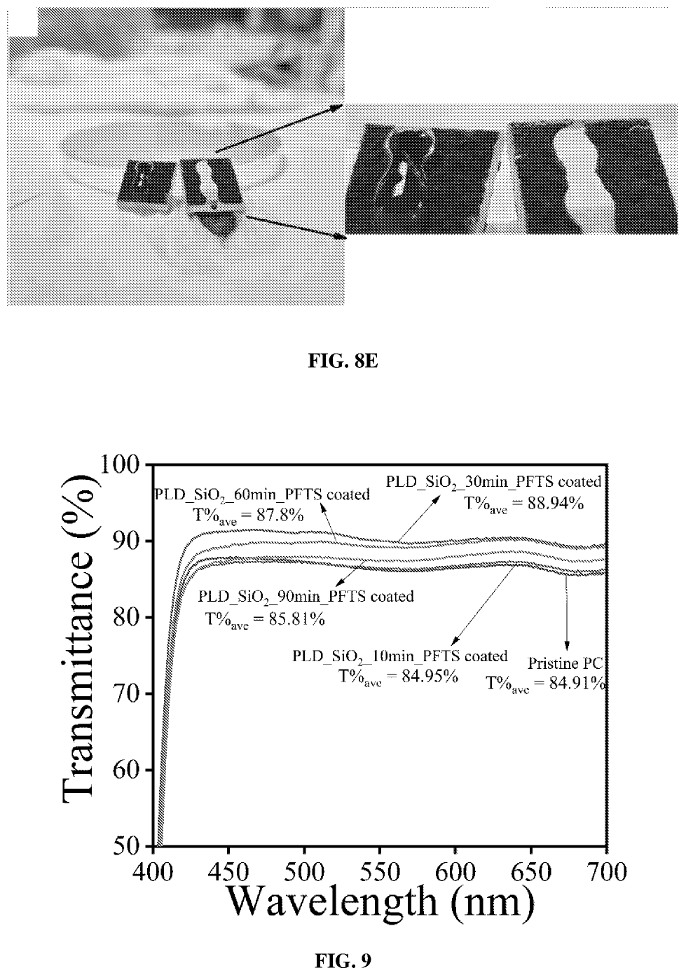

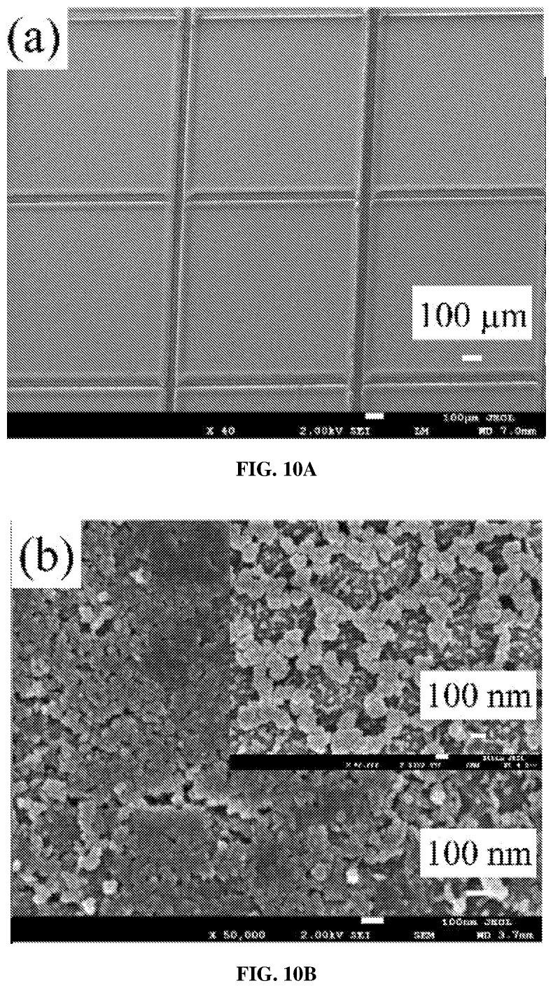

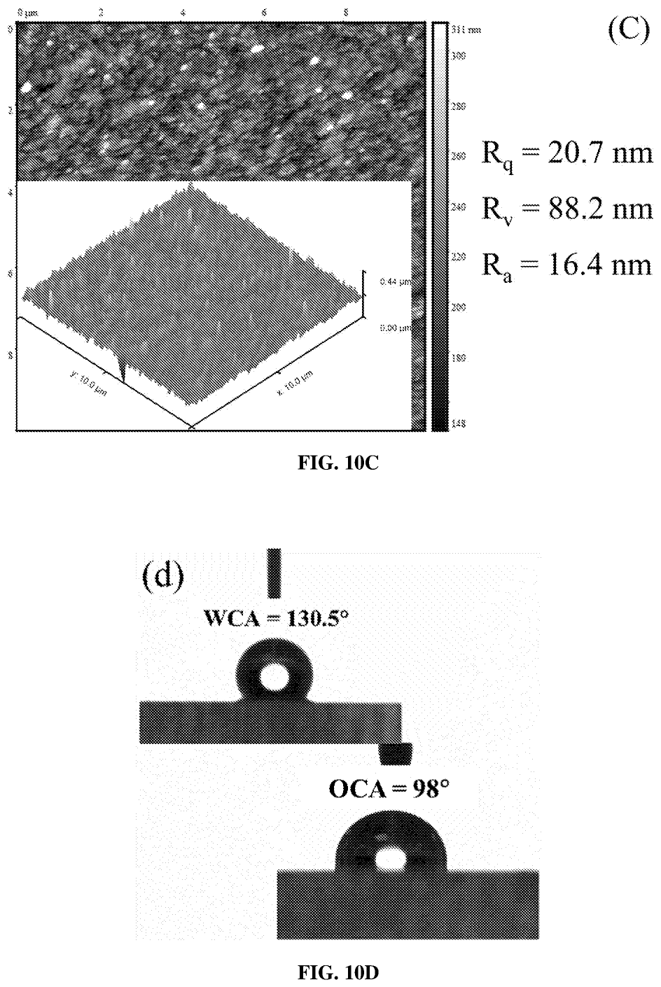

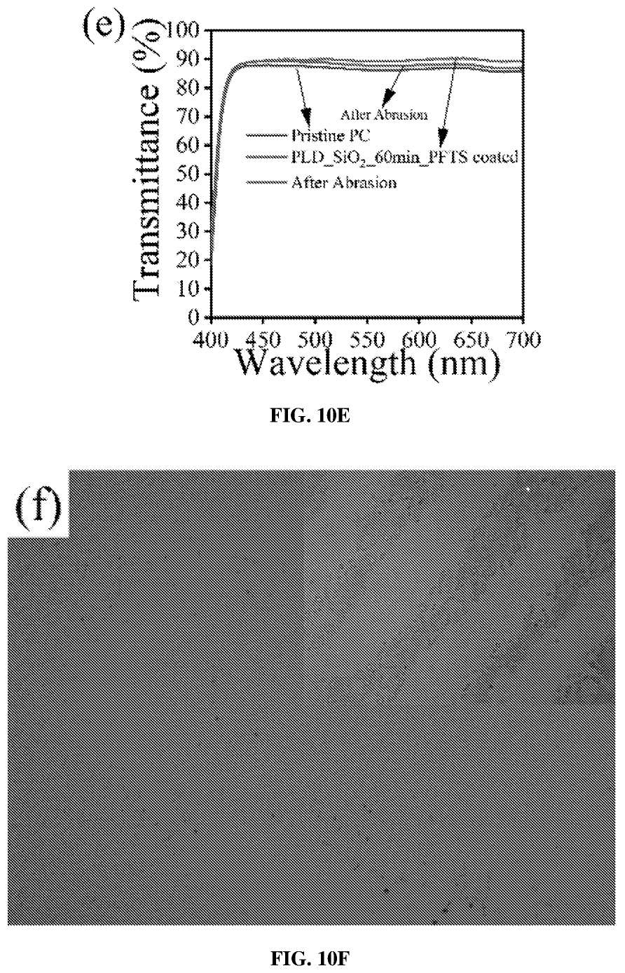

FIG. 1 schematically illustrates the procedure of fabricating silica nanoparticle film with PFTS coating on PC surface according to an embodiment. The whole process is relatively fast and does not require substrate heating.

### Example 4.1: Surface Topography and Thickness Effect on Wetting Behaviour and Mechanical Durability

The pulsed laser deposition of silica film was carried out for 4 different durations: 10 min, 30 min, 60 min and 90 min to study the effect of topography and thickness on the wetting behavior as well as the mechanical durability.

Surface morphology of the PFTS coated silica nanoparticle film deposited at different time duration was investigated through SEM and AFM. As shown in the SEM image in FIG. 2A to FIG. 2L, similar morphology was observed for 4 coating duration except the cluster size grew larger at longer coating durations. Film thickness became thicker with deposition time as shown in TABLE 1.

TABLE 1
Surface roughness parameters measurement and
film thickness measurement at different silica
nanoparticle film deposition duration

| Deposition | | | | | Thickness |
|---|---|---|---|---|---|
| Duration | R_{q} (nm) | Rᵥ (nm) | Rₐ (nm) | R_{f} (Rₐ/Rᵥ) | (nm) |
| 10 min | 50.9 | 144.5 | 42.9 | 0.296 | 17.9 ± 4.4 |
| 30 min | 48.9 | 169 | 38.4 | 0.227 | 42.3 ± 5.9 |
| 60 min | 55 | 165.1 | 40 | 0.242 | 97.1 ± 4.5 |
| 90 min | 48.6 | 130.9 | 39 | 0.297 | 142.3 ± 3.7 |

Surface roughness may play an important role in surface wetting behaviour. Surface topography as well as roughness parameters were investigated and measured through AFM shown in FIG. 2C, FIG. 2F, FIG. 2I and FIG. 2L. As indicated in TABLE 1, similar arithmetical mean roughness Ra and root-mean-square roughness R_{q} for 4 different deposition duration were observed. However, higher Ry was observed at 30 min and 60 min deposition time, which were correlated with the higher water and oil contact angles as listed in TABLE 2.

TABLE 2
Water contact angle and oil (diiodomethane) contact
angle measurement before and after abrasion
testing at different deposition duration.

| | Water | Water Contact | | Oil Contact |
|---|---|---|---|---|
| Deposition | Contact | Angle After | Oil Contact | Angle After |
| Duration | Angle (°) | Abrasion (°) | Angle (°) | Abrasion (°) |
| 10 min | 150.2 ± 4.1 | 94.5 ± 3.8 | 133 ± 1 | 71.6 ± 4.1 |
| 30 min | 158.2 ± 2.3 | 106.5 ± 7.5 | 128.2 ± 3.7 | 79 ± 3.6 |
| 60 min | 155.2 ± 1.8 | 129.2 ± 4.4 | 133.6 ± 3.3 | 98 ± 2.6 |
| 90 min | 150.4 ± 4.0 | 137.2 ± 4.2 | 118.7 ± 8.4 | 82 ± 7.0 |

As described herein, larger Rᵥ favours the amphiphobicity towards anti-fingerprint. Therefore, relatively great performance in terms of water and oil contact angles is expected. Decreasing of water and oil contact angles was observed at longer (90 min) deposition, caused by reduction of peaks and valleys resulting from larger cluster growth.

The inventors have found that silica nanoparticle film thickness contributed greatly on abrasion resistance. As shown in FIG. 3A and FIG. 3B, less significant reduction in water or oil contact angle can be observed at longer deposition durations. For deposition done at 60 min, water contact angle after abrasion remained about 130° while oil contact angle still above 90°. Therefore, this film provides greater mechanical abrasion resistance and was selected as the condition for detailed studies in the current work.

In summary, combining the results that were obtained, silica nanoparticle film deposited at 60 min followed with PFTS coating exhibited best performance in terms of transparency, surface wetting behavior as well as mechanical abrasion resistance.

60 min deposition of silica nanoparticle film followed with PFTS coating exhibited best results in terms of surface wetting behavior, transparency, and mechanical abrasion resistance. Therefore, the results disclosed herein are based on 60 min deposition of silica nanoparticle film with PFTS coating unless otherwise mentioned.

### Example 4.2: Surface Wettability

FIG. 4 shows the static contact angle profiles of water and oil for silica nanoparticle film without and with PFTS coating. The water contact angle (WCA) changed from completely wetting on PLD deposited silica nanoparticle film (401) to 155.2±1.8° (403) after PFTS decoration. The oil (diiodomethane) contact angle changed from complete wetting to 133.6±3.3° (refer 405 and 407). The sliding behavior of water and diiodomethane droplets were also tested for silica nanoparticle film with PFTS coating. Significantly low sliding angles for water (approximately 4°) were observed, while the sliding angles for diiodomethane were around 23°. Therefore, the coating is superhydrophobic and highly oleophobic.

### Example 4.3: Surface Physical Microstructure and Chemical Structure

Change of the surface property is caused by modification of its physical microstructure as well as the surface chemistry. SEM and AFM were used to characterize the surface physical structures in the current study. XPS was used to detect the surface chemistry composition. SEM and AFM images of as-prepared silica nanoparticle film with PFTS and without PFTS coating are shown in FIG. 5A and FIG. 5B, respectively. Surface morphology of silica nanoparticle via PLD deposition are well preserved after PFTS coating as similar nanostructures (when comparing FIG. 5A and FIG. 5B) as well as surface roughness (listed in TABLE 3) are observed.

TABLE 3
Roughness measurement comparison between nanoparticle
film with PFTS and without PFTS coating.

| | Silica nanoparticle film | Silica nanoparticle film |
|---|---|---|
| Roughness | with PFTS coating (nm) | without coating (nm) |
| R_{q} | 55.2 | 50.3 |
| Rᵥ | 165.1 | 160.7 |
| Rₐ | 40 | 39.1 |
| R_{f} (Rₐ/Rᵥ) | 0.242 | 0.243 |

As discussed above, it is a great challenge to fabricate anti-fingerprint surface with high optical transmittance, as surface roughness is indispensable for superamphiphobicity. However, high surface roughness may cause light scattering leading to a loss of light transmittance and even appearance (e.g., surface may become milky). A new roughness factor R_{f} was proposed for theoretical prediction of anti-fingerprint property of the surface coating. The roughness factor is defined as the ratio of arithmetical mean roughness (Rₐ) over the maximum height (Rᵥ), i.e. R_{f}=Rₐ/Rᵥ. For lower surface average roughness (Rₐ<1 μm) surface, relatively deeper valleys (higher Rᵥ) are favored to have better hydrophobic and oleophobic performance. For an anti-fingerprint surface, R_{f} should be no greater than 0.2451, which provides a gauge on the surface structure to enhance the anti-fingerprint property while retaining high optical transmittance. Surface of pristine PC was carefully modified through oxygen plasma treatment followed by deposition of silica nanoparticles.

As shown in FIG. 6A and FIG. 6B, oxygen plasma treatment significantly increases the surface roughness and creates peaks and valleys. Abundant oxygen bonding created by oxygen plasma, as indicated from XPS spectra (FIG. 6C), also helps promote the nucleation and growth of oxide nanoparticles. As shown in FIG. 5A, silica nanoparticles with an average size of 37.4±10.7 nm form clusters in the size of 188.5±36.5 nm are uniformly distributed on the surface without large aggregates. Surface roughness factor R_{f} was controlled below the recommended value of 0.2451.

Regarding to the surface chemistry transformation, XPS spectra are shown in FIG. 7A to FIG. 7E. FIG. 7A shows the XPS survey spectra of pristine PC, silica film and PFTS coated silica film. Significant increase of surface oxygen peak as well as the presence of silicon peak (located at 103.4 eV shown in FIG. 7D for high resolution spectra of Si 2p) after PLD deposition demonstrate that the silica film was coated on PC. The surface of silica was known to be intrinsically hydrophilic due to the presence of the silanol (Si—OH) groups. Silanol group have strong affinity with water through the formation of hydrogen bonds which results in formation of hydrophilic nanoparticle film on surface. The abundant hydroxyl groups (—OH) also provide chemical reaction sites with PFTS. The doublet peaks of C 1s located at 291.1 eV, 293.4 eV and F 1s peak located at 688.2 eV as shown in high resolution spectra FIG. 7B and FIG. 7E are characterized as —CF₂ and —CF₃ bond, which clearly indicate the successful deposition of PFTS on top of the silica film. The decoration of the fluorocarbon molecules results in the necessary lower surface energy needed for amphiphobicity.

### Example 4.4: Surface Transparency, Self-Cleaning and Anti-Fingerprint Property

FIG. 8A shows the digital image of as-prepared transparent PC substrate with PTFS coated silica film with water and oil droplets stably standing on the surface. The transmittance measured in the visible wavelength range 400 nm to 700 nm clearly indicates slight increase in light transmittance (shown in FIG. 8B). The average transmittance between wavelength 400 nm to 700 nm increases from 84.9% to 87.8%. Despite the slight increase in surface roughness there is no increase in the scattering of light as the surface features are much below the wavelength of visible light. On the contrary, the transmittance has increased with the silica nanoparticles coating, which indicates anti-reflective characteristic. This can be explicated through a single-layered anti-reflection film system, in which coating material with a lower refractive index than substrate is preferable. In present study, the silica film used was porous and could be treated as a composite of silica and air. This composite would lead to a considerably lower refractive index than silica dense film. Therefore, as-prepared silica nanoparticle film displays anti-reflective performance.

### Example 4.5: Effect of Deposition Duration on Light Transmittance at Visible Range

Effect of deposition duration on the light transmittance is reported herein.

The average light transmittance measurements at visible range between 400 nm to 700 nm for each deposition duration are indicated in FIG. 9. Coating deposited at 10 min showed almost identical average light transmittance as pristine PC substrate (Tₐᵥₑ @ 10 min deposition=84.95%; Tₐᵥₑ for pristine PC=84.91%). Highest average light transmittance (88.94%) was observed at 30 min deposition duration. Decreasing trend was observed at longer deposition period (Tₐᵥₑ @ 60 min deposition=87.8%, Tₐᵥₑ @ 90 min deposition=85.81%). Increased light transmittance observed at 30 min and 60 min deposition can be explained by the anti-reflective characteristics that has been described herein. Decrease of light transmittance at longer deposition duration is due to light absorbance in thicker film.

FIG. 8C and FIG. 8D demonstrate anti-fingerprint property. Fingerprints were created by holding thumb on surface for 2 s. Digital image and microscopic image comparison clearly indicate that fingerprints stick on pristine PC surface but not on coated PC surface.

The self-cleaning property has been employed to remove contaminants such as dust, dirt, and grease from solid surfaces. In present study, self-cleaning properties of the samples were investigated with titanium oxide powders as a model contaminant dust particles. As shown in FIG. 8E, titanium oxide powder was uniformly spread on the inclined PC surface. After dripping the water droplets, the silica nanoparticle film with PFTS coating demonstrates strong self-cleaning capability. The water droplets rolled off the superhydrophobic surface and immediately remove the powder along the path. As a comparison, the powder remained on pristine PC surface.

### Example 4.6: Mechanical Robustness and Durability of PFTS Coated Silica Coating

The major issues for practical usage of such coatings are mechanical toughness and durability. The coatings' mechanical robustness were analyzed by measuring coating adhesion and abrasion resistance using US Military Standards (MIL-C-48497). This specification is the most appropriate for optical coatings. Due to the superhydrophobic nature of the coating, the tape displays very weak or no adhesion to the substrate. Therefore, crosshatch test following the ASTM standard was performed to evaluate the quality of adhesion instead. FIG. 10A shows no coating delamination along the crosshatched lines which indicates a strong coating adhesion with the substrate.

Coating durability was further evaluated by rubbing the surface using a cheese cloth pad as described earlier. Surface morphology was altered (FIG. 10B) by the applied rubbing action. As indicated in FIG. 10C, surface roughness is reduced as high peaks and valleys were damaged by the applied shear force during the abrasion. Therefore, surface wettability is affected showing a drop of WCA to 129.2±4.4° and OCA (diiodomethane) to 98±2.6° as indicated in FIG. 10D. As indicated in transmittance measurement in FIG. 10E, although a slight drop of average transmittance was observed, higher average transmittance than prinstine PC were still achieved. Despite the drop in the water and oil contact angles, anti-fingerprint property still remains as shown in microscopic image FIG. 10F, which shows much reduced fingerprints when compared with the pristine PC substrate.

### Example 5: Conclusion

As disclosed herein, a facile method to prepare a highly transparent and amphiphobic coating with self-cleaning and anti-fingerprint properties was developed. Room temperature deposition of nanoporous silica film by pulse laser deposition created the desirable surface morphology in exemplified embodiments. The functionalization of silica nanoparticles by the low surface energy PFTS molecules was confirmed by the presence of C—F bonds shown in XPS analysis. Oxygen plasma treatment of PC substrate not only helped promote nucleation and growth of silica nanoparticles into desire morphology, but also enhanced adhesion strength between the coating and the substrate. Combination of enhanced transparency, superhydrophobic/oleophobic character, excellent mechanical durability and adhesion exhibit great potential for such coating for contaminant-sensitive optical and display applications.

By “comprising” it is meant including, but not limited to, whatever follows the word “comprising”. Thus, use of the term “comprising” indicates that the listed elements are required or mandatory, but that other elements are optional and may or may not be present.

By “consisting of” is meant including, and limited to, whatever follows the phrase “consisting of”. Thus, the phrase “consisting of” indicates that the listed elements are required or mandatory, and that no other elements may be present.

The inventions illustratively described herein may suitably be practiced in the absence of any element or elements, limitation or limitations, not specifically disclosed herein. Thus, for example, the terms “comprising”, “including”, “containing”, etc. shall be read expansively and without limitation. Additionally, the terms and expressions employed herein have been used as terms of description and not of limitation, and there is no intention in the use of such terms and expressions of excluding any equivalents of the features shown and described or portions thereof, but it is recognized that various modifications are possible within the scope of the invention claimed. Thus, it should be understood that although the present invention has been specifically disclosed by preferred embodiments and optional features, modification and variation of the inventions embodied therein herein disclosed may be resorted to by those skilled in the art, and that such modifications and variations are considered to be within the scope of this invention.

By “about” in relation to a given numerical value, such as for temperature and period of time, it is meant to include numerical values within 10% of the specified value.

The invention has been described broadly and generically herein. Each of the narrower species and sub-generic groupings falling within the generic disclosure also form part of the invention. This includes the generic description of the invention with a proviso or negative limitation removing any subject matter from the genus, regardless of whether or not the excised material is specifically recited herein.

Other embodiments are within the following claims and non-limiting examples. In addition, where features or aspects of the invention are described in terms of Markush groups, those skilled in the art will recognize that the invention is also thereby described in terms of any individual member or subgroup of members of the Markush group.

1. An amphiphobic coating comprising a polymeric substrate having an oxygen plasma-treated surface;
a silicon dioxide nanoporous layer comprising silicon dioxide nanoparticles disposed directly on the oxygen plasma-treated surface; and
a fluoroalkylsilane layer disposed directly on the silicon dioxide nanoporous layer.

2-3. (canceled)

4. The amphiphobic coating according to claim 1, wherein the silicon dioxide nanoparticles have an average size in the range from 25 nm to 50 nm.

5. The amphiphobic coating according to claim 1, wherein the silicon dioxide nanoparticles form clusters having a size in the range from 150 nm to 250 nm.

6. The amphiphobic coating according to claim 1, wherein the silicon dioxide nanoporous layer has a thickness in the range from 10 nm to 500 nm.

7. The amphiphobic coating according to claim 1, wherein the fluoroalkylsilane layer is a self-assembled layer.

8. The amphiphobic coating according to claim 1, wherein surface of the silicon dioxide nanoporous layer comprises hydroxyl groups, and wherein the fluoroalkylsilane layer disposed directly on the silicon dioxide nanoporous layer is covalently bonded to the silicon dioxide nanoporous layer via the hydroxyl groups.

9. (canceled)

10. The amphiphobic coating according to claim 1, wherein the fluoroalkylsilane layer is formed from a fluoroalkylsilane selected from the group consisting of trichloro (1H,1H,2H,2H-perfluorooctyl) silane, 1H,1H,2H,2H perfluorodecyltriethoxysilane, and combinations thereof.

11. The amphiphobic coating according to claim 1, wherein roughness factor R_{f} of the amphiphobic coating is 0.2451 or less.

12. The amphiphobic coating according to claim 1, wherein the amphiphobic coating exhibits a transmittance of at least 84% in the wavelength region from 400 nm to 700 nm.

13. The amphiphobic coating according to claim 1, wherein contact angle of water on the amphiphobic coating is more than 150°.

14. The amphiphobic coating according to claim 1, wherein contact angle of diiodomethane on the amphiphobic coating is more than 130°.

15. A method of preparing an amphiphobic coating, the method comprising providing a polymeric substrate having an oxygen plasma-treated surface;
depositing silicon dioxide directly on the oxygen plasma-treated surface by pulsed laser deposition to form a silicon dioxide nanoporous layer comprising silicon dioxide nanoparticles; and
depositing a fluoroalkylsilane directly on the silicon dioxide nanoporous layer to form a fluoroalkylsilane layer on the silicon dioxide nanoporous layer.

16. The method according to claim 15, wherein the fluoroalkylsilane is selected from the group consisting of trichloro (1H,1H,2H,2H-perfluorooctyl) silane, 1H, 1H,2H,2H perfluorodecyltriethoxysilane, and combinations thereof.

17. The method according to claim 15, wherein depositing a fluoroalkylsilane directly on the silicon dioxide nanoporous layer comprises contacting the silicon dioxide nanoporous layer with a solution comprising the fluoroalkylsilane and a liquid reagent.

18. The method according to claim 17, wherein the liquid reagent is selected from the group consisting of hexane and methanol.

19. The method according to claim 17, wherein concentration of the fluoroalkylsilane in the solution is in the range from 0.05 vol % to 0.15 vol %.

20. The method according to claim 17, wherein contacting the silicon dioxide nanoporous layer with the solution is carried out for a time period in the range of 5 minutes to 20 minutes.

21. The method according to claim 17, wherein depositing a fluoroalkylsilane directly on the silicon dioxide nanoporous layer further comprises drying the silicon dioxide nanoporous layer at a temperature in the range from 70° C. to 90° C. after it has contacted with the solution.

22-23. (canceled)

24. The method according to claim 15, wherein the method is carried out without heating.

25-26. (canceled)

27. An article of manufacture comprising an amphiphobic coating, the amphiphobic coating comprising a polymeric substrate having an oxygen plasma-treated surface, a silicon dioxide nanoporous layer comprising silicon dioxide nanoparticles disposed directly on the oxygen plasma-treated surface, and a fluoroalkylsilane layer disposed directly on the silicon dioxide nanoporous layer; or the amphiphobic coating prepared by a method comprising providing a polymeric substrate having an oxygen plasma-treated surface, depositing silicon dioxide directly on the oxygen plasma-treated surface by pulsed laser deposition to form a silicon dioxide nanoporous layer comprising silicon dioxide nanoparticles, and depositing a fluoroalkylsilane directly on the silicon dioxide nanoporous layer to form a fluoroalkylsilane layer on the silicon dioxide nanoporous layer, wherein the article is an optical component, sensor, lens, goggles, mirror, windshield, face shield, display, window, or cookware covers.
